(19) United States
(12) Patent Application Publication
(10) Pub. No.: US 2023/0180537 A1
(43) Pub. Date: Jun. 8, 2023

(54) LIGHT EMITTING DISPLAY DEVICE

(71) Applicant: Samsung Display Co., Ltd., Yongin-Si (KR)

(72) Inventors: DAWOON JUNG, Hwaseong-si (KR); Dae Won CHOI, Cheonan-si (KR); Su Bin BAE, Hwaseong-si (KR); Yu-Gwang JEONG, Anyang-si (KR)

(21) Appl. No.: 17/860,206

(22) Filed: Jul. 8, 2022

(30) Foreign Application Priority Data
Dec. 6, 2021 (KR) 10-2021-0172893

(51) Int. Cl. H01L 27/32; H01L 51/50

(52) U.S. Cl. CPC H01L 27/3248; H01L 51/5072; H01L 51/5056; H01L 27/3246; H01L 2251/305

(57) ABSTRACT

A light emitting display device includes a substrate, a transistor, a first insulating layer, a second insulating layer, a pixel electrode, a conductive member, a third insulating layer, and a light emitting material layer. The transistor overlaps the substrate. The first insulating layer overlaps the transistor. The second insulating layer overlaps the first insulating layer. The pixel electrode directly contacts the second insulating layer and is electrically connected to the transistor. The conductive member directly contacts at least one of the first insulating layer and the second insulating layer. The third insulating layer overlaps the second insulating layer, includes a hole, and includes an opening. The hole exposes the pixel electrode. The opening exposes the conductive member. The light emitting material layer overlaps the pixel electrode inside the hole, overlaps the third insulating layer, and has a discontinuity inside the opening.

### CROSS-REFERENCE TO RELATED APPLICATION

This application claims priority to Korean Patent Application No. 10-2021-0172893 filed in the Korean Intellectual Property Office on Dec. 6, 2021; the Korean Patent Application is incorporated by reference.

### BACKGROUND

### (a) Technical Field

The technical field is related to a light emitting display device.

### (b) Description of the Related Art

A light emitting display device may include light emitting diodes corresponding to pixels and may display an image by controlling brightness levels of the light emitting diodes. The light emitting display device does not require a separate light source and thus may be satisfactorily thin and light. A light emitting display device may display images with high luminance, a high contrast ratio, high color reproduction, and a high response speed.

Light emitting display devices may be applied to various electronic devices, such as smart phones, tablet computers, monitors, televisions, and display devices for vehicles.

The information disclosed in the Background section is for enhancement of understanding of the background of embodiments. The Background section may contain information that does not form the prior art that is already known in this country to a person of ordinary skill in the art.

### SUMMARY

A light emitting display device may include light emitting diodes. Each of the light emitting diodes may include a pixel electrode, a light emitting member, and a common electrode configured for emitting light. The light emitting member may include layers, and at least some of the layers may span multiple pixels. If no discontinuities are provided in the layers, a current intended for a pixel may leak to an adjacent pixel, and the adjacent pixel may unintentionally emit light, and/or luminance of the adjacent pixel may unwantedly increase.

Embodiments may be related to a light emitting display device that may substantially prevent unwanted emission of light caused by leakage of current from adjacent pixels.

An embodiment may be related to a light emitting display device that includes the following elements: a substrate; a transistor disposed on the substrate; a first insulating layer disposed on the transistor; a second insulating layer disposed on the first insulating layer; a pixel electrode disposed on the second insulating layer and electrically connected to the transistor; an etch stopper disposed on the first insulating layer or the second insulating layer; a pixel defining layer disposed on the second insulating layer and having an opening overlapping the etch stopper; and a light emitting member disposed on the pixel electrode and the pixel defining layer. The light emitting member includes a first light emitting part, a charge generating layer, and a second light emitting part, and the light emitting member is cut off in the opening.

The opening may have an undercut structure.

The opening may gradually narrow and then widen in a depth direction.

The charge generating layer may include an n-type charge generating layer and a p-type charge generating layer, and the charge generating layer may be divided at both sides of the etch stopper.

The charge generating layer may include a portion disposed on the etch stopper.

The light emitting display device may further include a common electrode disposed on the light emitting member. The common electrode may be cut off in the opening.

The common electrode may include a portion disposed on the etch stopper.

The etch stopper may include a transparent conductive oxide layer.

The etch stopper may be disposed on the second insulating layer. The etch stopper may include a transparent conductive oxide layer, a metal layer, and a transparent conductive oxide layer that may be sequentially stacked.

The etch stopper may be made of the same material as the pixel electrode in the same process.

The light emitting display device may further include a connector that is disposed between the first insulating layer and the second insulating layer and to which the pixel electrode is connected. The connector may be one electrode of the transistor, or may be connected to the one electrode. The etch stopper may be made of the same material as the connector in the same process.

The opening may be formed through the pixel defining layer and the second insulating layer.

Each of the first light emitting part and the second light emitting part may include a hole transport layer, an electron transport layer disposed on the hole transport layer, and a light emitting layer disposed between the hole transport layer and the electron transport layer and overlapping the pixel electrode.

An embodiment may be related to a light emitting display device that includes the following elements: a substrate; a transistor disposed on the substrate; a first insulating layer disposed on the transistor; a second insulating layer disposed on the first insulating layer; a pixel electrode disposed on the second insulating layer and electrically connected to the transistor; an etch stopper disposed on the first insulating layer or the second insulating layer; a pixel defining layer disposed on the second insulating layer and having an opening overlapping the etch stopper; and a light emitting member disposed on the pixel electrode, the pixel defining layer, and the etch stopper. A portion of the light emitting member disposed on the pixel defining layer and a portion of the light emitting member disposed on the etch stopper may be separated.

The etch stopper may not be connected to other electrodes or signal lines.

The etch stopper may be disposed on the second insulating layer. The etch stopper may include a transparent conductive oxide layer.

The etch stopper may be made of the same material as the pixel electrode in the same process.

The etch stopper may be in contact with the first insulating layer. The etch stopper may include a refractory metal layer.

The light emitting display device may further include a common electrode disposed on the light emitting member. The common electrode may include a portion disposed on the etch stopper.

The opening may have an undercut structure.

An embodiment may be related to a light emitting display device. The light emitting display device may include a substrate, a transistor, a first insulating layer, a second insulating layer, a pixel electrode, a conductive member, a third insulating layer, and a light emitting material layer. The transistor may overlap the substrate. The first insulating layer may overlap the transistor. The second insulating layer may overlap the first insulating layer. The pixel electrode may directly contact the second insulating layer and may be electrically connected to the transistor. The conductive member may directly contact at least one of the first insulating layer and the second insulating layer. The third insulating layer may overlap the second insulating layer, may include a hole, and may include an opening. The hole may (partially) expose the pixel electrode. The opening may (partially) expose the conductive member. The light emitting material layer may overlap the pixel electrode inside the hole, may overlap the third insulating layer, and may have a discontinuity inside the opening.

The opening may have an undercut structure.

A first section of the opening may be positioned between a second section of the opening and a third section of the opening in a depth direction of the opening (i.e., a direction perpendicular to the substrate) and may be narrower than each of the second section of the opening and the third section of the opening (in a direction parallel to the substrate).

The light emitting material layer may include a charge generating layer. The charge generating layer may be partially positioned inside the opening and may (partially) expose the conductive member inside the opening.

The charge generating layer may include a disconnected portion. The disconnected portion may be disposed inside the opening and may overlap the conductive member. The disconnected portion may be deemed a charge generating material member that is spaced (by air gaps) from portions of the charge generating layer that overlap the third insulating layer.

The light emitting display device may include a common electrode material layer. The common electrode material layer may overlap each of the light emitting material layer and the third insulating layer. The common electrode material layer may have a gap inside the opening.

The common electrode material layer may include a disconnected portion. The disconnected portion may be disposed inside the opening and may overlap the conductive member. The disconnected portion may be deemed a common electrode material member that is spaced (by air gaps) from portions of the common electrode material layer that overlap the third insulating layer.

The conductive member may include a transparent conductive oxide layer.

The conductive member may include a first transparent conductive oxide layer, a metal layer, and a second transparent conductive oxide layer that are be sequentially stacked. At least one of the first transparent conductive oxide layer and the second transparent conductive oxide layer may directly contact the second insulating layer.

The conductive member may be made of a same material as the pixel electrode in a same process step.

The light emitting display device may include a connector. The connector may be disposed between the first insulating layer and the second insulating layer, may be electrically connected to the pixel electrode, and may be electrically connected to at least one of a semiconductor layer of the transistor, a drain electrode of the transistor, and a source electrode of the transistor. The conductive member may be made of a same material as the connector in a same process step.

The opening may extend through the third insulating layer and the second insulating layer.

The light emitting material layer may include a hole transport layer, an electron transport layer (overlapping the hole transport layer), and a light emitting layer disposed between the hole transport layer and the electron transport layer and overlapping the pixel electrode.

An embodiment may be related to a light emitting display device. The light emitting display device may include a substrate, a transistor, a first insulating layer, a second insulating layer, a pixel electrode, a conductive member, a third insulating layer, and a light emitting material layer. The transistor may overlap the substrate. The first insulating layer may overlap the transistor. The second insulating layer may overlap the first insulating layer. The pixel electrode may directly contact the second insulating layer and may be electrically connected to the transistor. The conductive member may directly contact at least one of the first insulating layer and the second insulating layer. The third insulating layer may overlap the second insulating layer, may include a hole, and may include an opening. The hole may (partially) expose the pixel electrode. The opening may (partially) expose the conductive member. The light emitting material layer may overlap the pixel electrode inside the hole, may overlap the third insulating layer, and may include two disconnected portions that are disposed inside the opening, are spaced from each other by a gap, and are electrically disconnected from each other.

The conductive member may be electrically disconnected from all transistors of the light emitting display device.

The conductive member may directly contact the second insulating layer and may include a transparent conductive oxide layer.

The conductive member may be made of a same material as the pixel electrode in a same process step.

The conductive member may directly contact the first insulating layer and may include a refractory metal layer.

The light emitting display device may include a common electrode material layer. The common electrode material layer may overlap the light emitting material layer inside the hole. The common electrode material layer may have a discontinuity inside the opening.

The opening may have an undercut structure.

According to embodiments, unwanted emission of light may be substantially prevented or minimized. Advantageously, the quality of images displayed by a light emitting display device may be satisfactory.

### BRIEF DESCRIPTION OF THE DRAWINGS

FIG. 1 illustrates a schematic exploded perspective view of a display device according to an embodiment.

FIG. 2 illustrates a schematic top plan view of area “A” indicated in FIG. 1 according to an embodiment.

FIG. 3 illustrates a schematic cross-sectional view of a vicinity of a peripheral area of a display panel according to an embodiment.

FIG. 4 illustrates a schematic top plan view of pixels disposed in a display area in a light emitting display device according to an embodiment.

FIG. 5 illustrates a cross-sectional view of a light emitting display device taken along line A-A′ indicated in FIG. 4 according to an embodiment.

FIG. 6 illustrates a schematic cross-sectional view of a light emitting member in a light emitting display device according to an embodiment.

FIG. 7, FIG. 8, FIG. 8, FIG. 9, FIG. 10, FIG. 11, FIG. 12, and FIG. 13 illustrate cross-sectional views of structures associated with process steps of a manufacturing method of a light emitting display device according to one or more embodiments.

FIG. 14 illustrates a cross-sectional view of a light emitting display device taken along line A-A′ indicated in FIG. 4 according to an embodiment.

FIG. 15 illustrates a schematic cross-sectional view of one pixel area in a display panel according to an embodiment.

FIG. 16 illustrates a schematic cross-sectional view of one pixel area in a display panel according to an embodiment.

FIG. 17 illustrates a schematic cross-sectional view of one pixel area in a display panel according to an embodiment.

### DETAILED DESCRIPTION OF EMBODIMENTS

Examples of embodiments are described reference to the accompanying drawings.

Although the terms “first,” “second,” etc. may be used to describe various elements, these elements should not be limited by these terms. These terms may be used to distinguish one element from another element. A first element may be termed a second element without departing from teachings of one or more embodiments. The description of an element as a “first” element may not require or imply the presence of a second element or other elements. The terms “first,” “second,” etc. may be used to differentiate different categories or sets of elements. For conciseness, the terms “first,” “second,” etc. may represent “first-category (or first-set),” “second-category (or second-set),” etc., respectively.

When a first element is referred to as being “on” a second element, the first element can be directly on the second element, or one or more intervening elements may be present between the first element and the second element. When a first element is referred to as being “directly on” a second element, no intended intervening elements (except for environmental elements such air) may be present between the first element and the second element.

The word “comprise” and variations such as “comprises” or “comprising” may indicate the inclusion of stated elements and may not indicate the exclusion of any other elements.

The term “connect” may mean “directly connect” or “indirectly connect.” The term “connect” may mean “mechanically connect” and/or “electrically connect.” The term “connected” may mean “electrically connected” or “electrically connected through no intervening transistor.” The term “insulate” may mean “electrically insulate” or “electrically isolate.” The term “conductive” may mean “electrically conductive.” The term “drive” may mean “operate” or “control.” The term “include” may mean “be made of.” The term “adjacent” may mean “immediately adjacent.” The expression that an element extends in a particular direction may mean that the element extends lengthwise in the particular direction and/or that the lengthwise direction of the element is in the particular direction. The term “defined” may mean “formed” or “provided.” The expression that a space or opening overlaps an object may mean that (the position of) the space or opening overlaps with (the position of) the object and/or that the space or opening exposes the object. The term “overlap” may be equivalent to “be overlapped by.” The expression that a first element overlaps with a second element in a plan view may mean that the first element overlaps the second element in direction perpendicular to a substrate. The term “member” may mean “layer.” A member/layer may include disconnected/spaced portions that include substantially the same stack structure and/or are formed of substantially the same material(s). The disconnected/spaced portions of the same member/layer may be substantially electrically disconnected from each other. The disconnected/spaced portions of the same member/layer may be treated as individual elements. The term “light emitting member” may mean “light emitting material layer.” The term “common electrode” may mean “common electrode material layer.” The term “process” may mean “process step.” The term “etch stopper” may mean “electrically conductive member” or “conductive member.” The expression “A, B, . . . , and/or C” may mean “at least one of A, B, . . . , and C.”

In the drawings, ‘x’ may mean a first direction, ‘y’ may mean a second direction perpendicular to the first direction, and z may mean a third direction perpendicular to the first direction and the second direction.

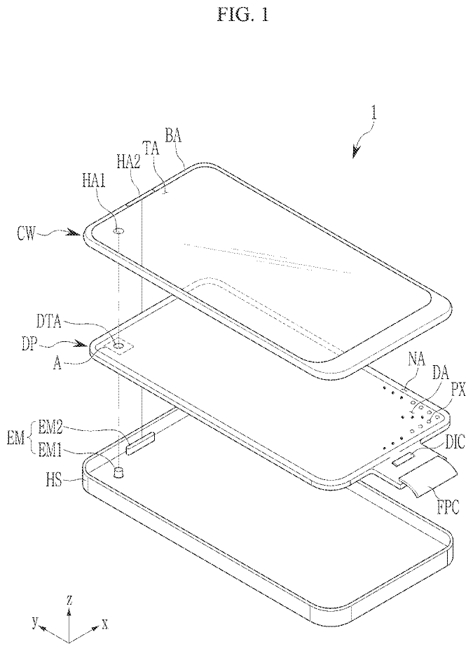

FIG. 1 illustrates a schematic exploded perspective view of a light emitting display device 1 according to an embodiment.

The light emitting display device 1 (display device 1) may be applied to an electronic device such as a smart phone, a mobile phone, a tablet computer, a multimedia player, or a game machine. The display device 1 may be rigid. The display device 1 may include a flexible portion capable of bending, folding, and/or rolling. The display device 1 may display an image in a third direction z and on a front surface in a plane defined by a first direction x and a second direction y. The display device 1 may include a display panel DP, a cover window CW, one or more electronic modules EM, and a housing HS.

The display panel DP may include a display area DA and a non-display area NA. The display area DA may display an image in response to input signals and may correspond to a screen. The non-display area NA may not display images in response to input signals and may surround at least a portion of the display area DA.

The display panel DP may include pixels PX arranged in the display area DA, and an image may be displayed by a combination of light emitted by the pixels PX. The display panel DP may include pixel circuits and signal lines for driving the pixels PX. The display panel DP may be a light emitting display panel including light emitting diodes, and each light emitting diode may be included in a pixel PX. The display panel DP may include a touch sensor layer capable of sensing a touch.

The display panel DP may include an opening DTA. The opening DTA may be positioned in the display area DA. The opening DTA may pass through the display panel DP. Some of the pixels PX may surround the opening area DTA.

The non-display area NA of the display panel DP may include or accommodate a driving part that generates and/or processes various signals for driving the pixels PX. For example, the driving part may include a data driver that applies data voltages to the pixels PX, a gate driver that applies gate voltages to the pixels PX, and a signal controller that controls the data driver and the gate driver. The gate driver may be integrated in the non-display area NA. The data driver and the signal controller may be provided as a driving integrated circuit chip DIC, and may be mounted in the non-display area NA. The driving integrated circuit chip DIC may be mounted on a flexible printed circuit film FPC or the like to be electrically connected to the display panel DP.

The cover window CW may be positioned on the display panel DP to protect the display panel DP from an external impact and to transmit an image displayed on the display panel DP. The cover window CW may be attached to the display panel DP by an adhesive such as an optically clear adhesive (OCA) or an optically clear adhesive resin (OCR). The cover window CW may be coated on the display panel DP. The cover window CW may include a transmission area TA and a blocking area BA. The transmission area TA may be optically transparent and may transmit light. The blocking area BA may have lower light transmittance than the transmission area TA. The blocking area BA may define a shape of the transmission area TA. The blocking area BA may surround the transmission area TA. The blocking area BA may display a predetermined color. The blocking area BA overlaps the non-display area NA of the display panel DP to block the non-display area NA from being viewed from the outside.

The cover window CW may include a first hole HA1 and a second hole HA2. Each of the first hole HA1 and the second hole HA2 may overlap one of the electronic modules EM. The electronic modules EM may operate by receiving signals provided through the first hole HA1 and the second hole HA2.

The first hole HA1 may be positioned in the transmission area TA, and the second hole HA2 may be positioned in the blocking area BA. Unlike the illustrated example, the first hole HA1 and the second hole HA2 may be positioned in areas opposite to each other, or both of them may be positioned in the transmission area TA or the blocking area BA. The number, shapes, and sizes of the holes corresponding to electronic modules may depend on embodiments. The first hole HA1 may have a circular shape, and the second hole HA2 may extend in the first direction x.

Each of the first hole HA1 and the second hole HA2 may be a predetermined depression recessed from a rear surface of the cover window CW. The depression may depth that is less than a thickness of the cover window CW. The first hole HA1 may overlap the opening area DTA of the display panel DP.

The electronic modules EM may include functional modules related to the operation of the display device 1. The electronic modules EM may be electrically connected to the display panel DP through a connector or the like. For example, the electronic modules EM may include a camera, a sensor, a speaker, and/or a microphone. The electronic modules EM may include a first electronic module EM1 and a second electronic module EM2.

The first electronic module EM1 may sense a subject through the opening DTA and the first hole HA1. The first electronic module EM1 may receive an input transmitted through the opening DTA and the first hole HA1, and/or may provide an output through the opening DTA and the first hole HA1. The first electronic module EM1 may be/include a light emitting module, a light sensing module, and/or a photographing module. For example, the first electronic module EM1 may include at least one of a light emitting module for outputting infrared rays, a CMOS sensor for sensing infrared rays, and a camera module for photographing a subject.

The second electronic module EM2 may collect a sound signal such as voice through the second hole HA2, and/or may provide a sound signal such as processed voice to the outside. For example, the second electronic module EM2 may include at least one of a sound input module and a sound output module. The sound input module may include a microphone capable of receiving a sound signal. The sound output module may include a speaker that outputs sound data as a sound signal.

Unlike the illustrated, the electronic modules EM may be configured as a single module, may include more electronic modules, and/or may be disposed at different positions.

The housing HS may be combined with the cover window CW to form an appearance of the display device 1. The housing HS may be made of a material with high rigidity, such as metal, glass, or plastic. The display panel DP and the electronic module EM may be positioned in an inner space of the display device 1 enclosed by the cover window CW and the housing HS.

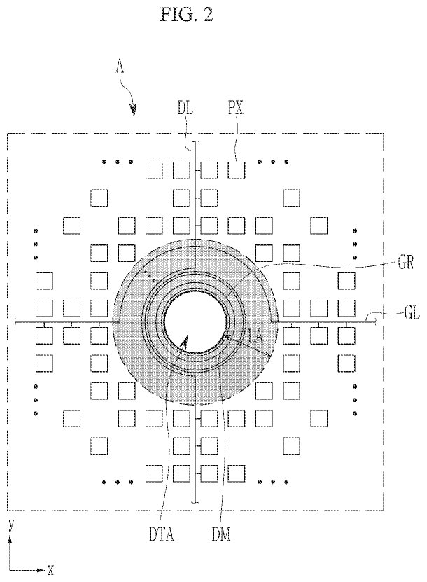

FIG. 2 illustrates a schematic top plan view of area “A” indicated in FIG. 1 according to an embodiment.

Referring to FIG. 2, the display panel DP may include the opening DTA and a peripheral area LA surrounding the opening DTA. The peripheral area LA may be positioned between the opening DTA and the display area DA. The peripheral area LA may have a donut-like shape. The peripheral area LA may be a buffer area that prevents damage to signal lines GL and DL during laser irradiation to form the opening DTA.

The display panel DP may include the signal lines GL and DL and the pixels PX positioned on the substrate. Each pixel PX may be connected to corresponding ones of the signal lines GL and DL. The signal lines GL and DL may include a gate line GL for transmitting a gate signal to the pixel PX and may include a data line DL for transmitting a data voltage to the pixel PX. The gate line GL and the data line DL may each bypass the opening DTA and may each include a substantially semicircular portion. In addition to the gate line GL and the data line DL are illustrated in FIG. 2, the pixel PX may be connected to other signal lines, such as a driving voltage line and an initialization voltage line.

A groove GR and a dam DM may be positioned in the peripheral area LA. The groove GR may be positioned between the opening DTA and the dam DM. The dam DM and the groove GR may surround the opening DTA. The dam DM may surround the groove GR. The groove GR and the dam DM may each have a substantially ring shape. Although one groove GR and one dam DM are illustrated, a plurality of grooves GR and a plurality of dams DM disposed at predetermined distances may be present.

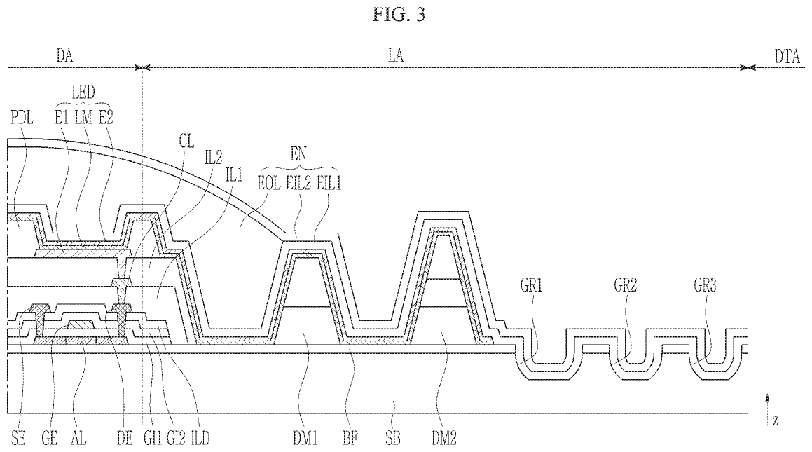

FIG. 3 illustrates a schematic cross-sectional view of a vicinity of a peripheral area LA of a display panel according to an embodiment.

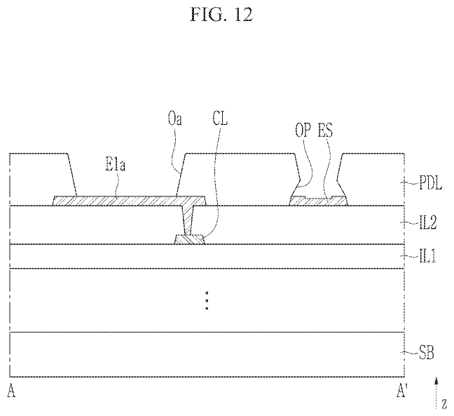

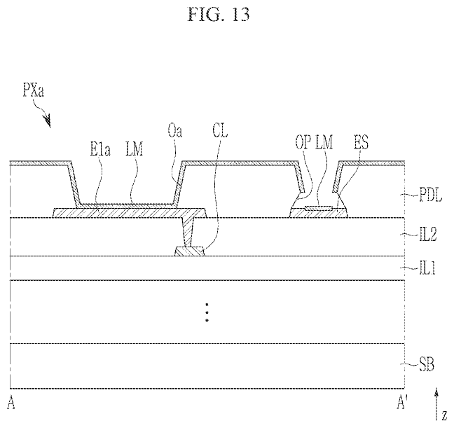

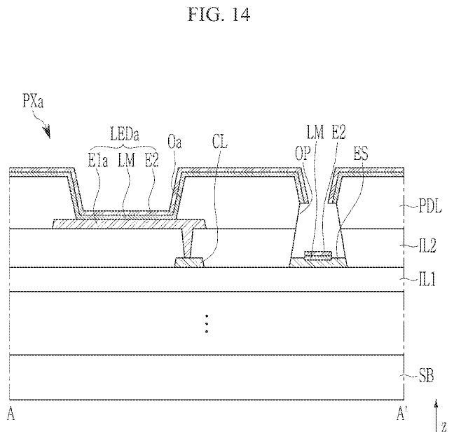

FIG. 3 illustrates a schematic cross-sectional structure of the peripheral area LA of the display panel DP. The display area DA and the opening DTA are positioned at opposite sides of the peripheral area LA. The display area DA is described with reference to FIG. 14 to FIG. 16.

The display panel DP may include a substrate SB spanning the display area DA and the peripheral area LA. A buffer layer BF may be positioned on the substrate SB. The buffer layer BF may span the display area DA and the peripheral area LA.

On the buffer layer BF, ends of a first gate insulating layer GI1, a second gate insulating layer GI2, an interlayer insulating layer ILD, a first insulating layer IL1, a second insulating layer IL2, and a pixel defining layer PDL may be positioned at/near a boundary between the display area DA and the peripheral area LA. The first gate insulating layer GI1, the second gate insulating layer GI2, the interlayer insulating layer ILD, the first insulating layer IL1, the second insulating layer IL2, and the pixel defining layer PDL may be substantially positioned in the display area DA and may have end portions positioned in the peripheral area LA. The first insulating layer IL1 may cover side surfaces of the first gate insulating layer GI1, the second gate insulating layer GI2, and the interlayer insulating layer ILD. The second insulating layer IL2 may cover a side surface of the first insulating layer IL1. The first gate insulating layer GI1, the second gate insulating layer GI2, and the interlayer insulating layer ILD may each be an inorganic insulating layer, and the first insulating layer IL1, the second insulating layer IL2, and the pixel defining layer PDL may each be an organic insulating layer. The first insulating layer IL1 and the second insulating layer IL2 may be referred to as a first planarization layer and a second planarization layer, respectively.

One or more grooves GR1, GR2, and GR3 may be positioned in the peripheral area LA. The grooves GR1, GR2, and GR3 may be formed to a predetermined depth of the substrate SB and may penetrate through the buffer layer BF. The grooves GR1, GR2, and GR3 may be formed by providing a mask pattern on the buffer layer BF and etching the buffer layer BF and the substrate SB through openings of the mask pattern. The grooves GR1, GR2, and GR3 may include a first groove GR1, a second groove GR2, and a third groove GR3 spaced apart from each other. The third groove GR3 may surround the opening DTA, the second groove GR2 may surround the third groove GR3, and the first groove GR1 may surround the second groove GR2. Although three grooves GR1, GR2, and GR3 are illustrated, more or fewer grooves may be positioned in the peripheral area LA. At least one of the first gate insulating layer GI1, the second gate insulating layer GI2, and the interlayer insulating layer ILD may extend to an area in which the grooves GR1, GR2, and GR3 are formed, and the grooves GR1, GR2, and GR3 may be formed through the extending layer(s).

In the peripheral area LA, one or more dams DM1 and DM2 may be present. The dams DM1 and DM2 may include a first dam DM1 and a second dam DM2 spaced apart from each other. The second dam DM2 may surround the opening DTA, and the first dam DM1 may surround the second dam DM2. The first dam DM1 and the second dam DM2 may be positioned on the buffer layer. The first dam DM1 and the second dam DM2 may each include one or more layers. The first dam DM1 and the second dam DM2 may control spreading of a material of an organic layer EOL of an encapsulation layer EN. For example, the material may be an organic material such as a monomer. Each layer of the first dam DM1 and the second dam DM2 may be formed of the same material as a corresponding one of the first insulating layer IL1, the second insulating layer IL2, and the pixel defining layer PDL in the same process. For example, the first dam DM1 may include a lower layer formed of the same material as the first insulating layer IL1 or the second insulating layer IL2 in the same process, and may include an upper layer formed of the same material as the pixel defining layer PDL in the same process. The second dam DM2 may include a lower layer formed of the same material as the first insulating layer IL1 in the same process, may include an intermediate layer formed of the same material in the same process as the second insulating layer IL2, and may include an upper layer formed of the same material as the pixel defining layer PDL in the same process. Although two dams DM1 and DM2 are illustrated, more or fewer dams may be positioned in the peripheral area LA.

A light emitting member LM (or light emitting material layer LM) and a common electrode E2 (or common electrode material layer E2) may be substantially positioned in the display area DA and may extend to the peripheral area LA to overlap/cover the dams DM1 and DM2.

The encapsulation layer EN may be positioned in the display area DA and may extend to the peripheral area LA. An edge of the organic layer EOL of the encapsulation layer EN may be positioned between the display area DA and the first dam DM1 or between the display area DA and the second dam DM2. A first inorganic layer EIL1 and a second inorganic layer EIL2 of the encapsulation layer EN may extend onto the dams DM1 and DM2, and may extend into the grooves GR1, GR2, and GR3. Accordingly, a contact area between the first inorganic layer EIL1 and the second inorganic layer EIL2 may increase, so that adhesion between the first inorganic layer EIL1 and the second inorganic layer EIL2 may increase. Therefore, the encapsulation layer EN may effectively prevent moisture, oxygen, and the like from entering the display area DA from the opening DTA through the peripheral area LA.

Referring to FIG. 1, FIG. 2, and FIG. 3, the first electronic module EM1 may be exposed by the opening DTA in the display device 1. An inner surface of the opening DTA may be defined by edges of the substrate SB, the buffer layer BF, the first inorganic layer EIL1, and the second inorganic layer EIL2. Respective edge side surfaces of the substrate SB, the buffer layer BF, the first inorganic layer EIL1, and the second inorganic layer EIL2 may be aligned with each other to define the opening DTA.

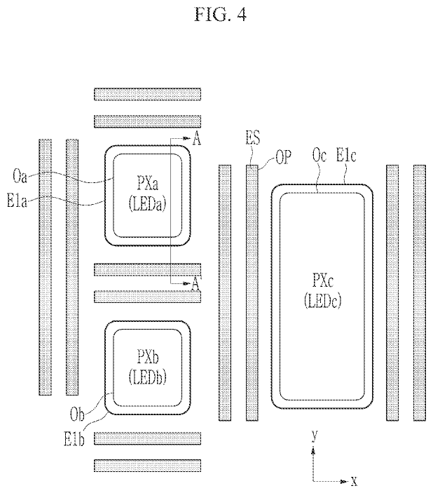

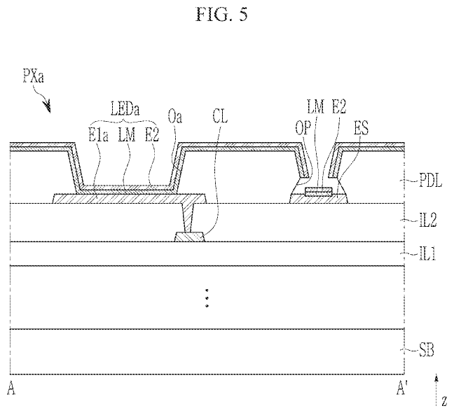

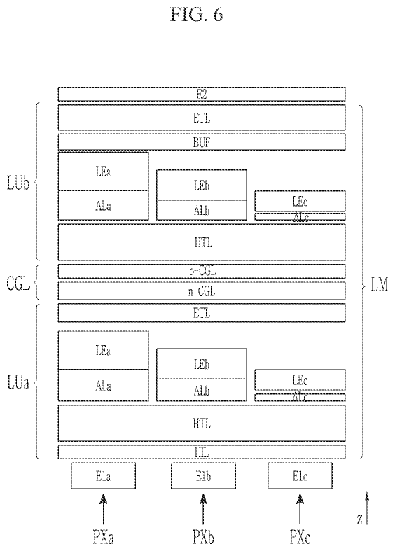

FIG. 4 illustrates a schematic top plan view of pixels disposed in a display area in a light emitting display device according to an embodiment. FIG. 5 illustrates a cross-sectional view of a light emitting display device taken along line A-A′ indicated in FIG. 4 according to an embodiment.

Referring to FIG. 1, FIG. 2, FIG. 3, and FIG. 4, pixels PXa, PXb, and PXc are disposed in the display area DA of the display panel DP. Although three pixels are shown, sets of pixels PXa, PXb, and PXc may be regularly disposed in a matrix form in the display area DA. The pixels PXa, PXb, and PXc may include a first pixel PXa, a second pixel PXb, and a third pixel PXc. The first pixel PXa, the second pixel PXb, and the third pixel PXc may display different colors, respectively, and each of them may display one of the primary colors. For example, one of the first pixel PXa, the second pixel PXb, and the third pixel PXc may display red, another may display green, and the other may display blue. For example, the first pixel PXa may display red, the second pixel PXb may display green, and the third pixel PXc may display blue.

The first pixels PXa, the second pixels PXb, and the third pixels PXc may be evenly distributed. First pixels PXa and second pixels PXb may be alternately disposed along the second direction y. Sets of first and second pixels PXa and PXb and third pixels PXc may be alternately disposed in the first direction x. The arrangements of the pixels PXa, PXb, and PXc may depend on embodiments.

One or more etch stoppers ES (or electrically conductive members ES) may be positioned between the first pixel PXa and the second pixel PXb. One or more etch stoppers ES may be positioned between the first pixel PXa and the third pixel PXc, and between the second pixel PXb and the third pixel PXc. The etch stopper ES may extend substantially in the first direction x or substantially in the second direction y.

Referring to FIG. 4 and FIG. 5, the display panel DP may include the substrate SB and layers and elements positioned on the substrate SB. The first insulating layer IL1 may be positioned on the substrate SB. A transistor, a capacitor, and the like for driving the pixels PXa, PXb, and PXc may be positioned between the substrate SB and the first insulating layer IL1 and are described with reference to FIG. 14 to FIG. 16.

A connector CL may be positioned on the first insulating layer IL1. The connector CL may be electrically connected to an electrode of the transistor. The connector CL may be an electrode of the transistor. The connector CL may have a multi-layered structure. For example, the connector CL may have a triple-layered structure including a lower layer that may be made of a refractory metal such as titanium (Ti), molybdenum (Mo), chromium (Cr), or tantalum (Ta); an intermediate layer that may be made of a metal having low resistivity, such as aluminum (Al), copper (Cu), or silver (Ag); and an upper layer that may be made of a refractory metal such as titanium (Ti), molybdenum (Mo), chromium (Cr), or tantalum (Ta).

The second insulating layer IL2 may be positioned on the first insulating layer IL1 and the connector CL. Pixel electrodes E1a, E1b, and E1c and the etch stopper ES may be positioned directly on the second insulating layer IL2. The pixel electrodes E1a, E1b, and E1c may each be electrically connected to a corresponding transistor. Each of the pixel electrodes E1a, E1b, and E1c may be connected to a corresponding connector CL through a contact hole formed in the second insulating layer IL2; the connector CL may be electrically connected to an electrode of the transistor or may be an electrode of the transistor (that is electrically connected to a semiconductor layer of the transistor). Adjacent ones of the pixel electrodes E1a, E1b, and E1c may be positioned at opposite sides of the etch stopper ES. The etch stopper ES may not be electrically connected to (i.e., may be electrically disconnected from) all the transistors, electrodes, signal lines, circuits, and the like of the display device 1, and may be electrically insulated/isolated without receiving any electrical signals (e.g., current or voltage). The etch stopper ES may maintain a common voltage (also referred to as a low potential power voltage). The etch stopper ES may be formed of the same material(s) as the pixel electrodes E1a, E1b, and E1c. The etch stopper ES may be formed in the same process as the pixel electrodes E1a, E1b, and E1c. The etch stopper ES may have a multi-layered structure. For example, the etch stopper ES may be a triple layer in which a first transparent conductive oxide layer (for example, an indium tin oxide (ITO) layer), a metal layer (for example, a silver (Ag) layer), and a second transparent conductive oxide layer (for example, another ITO layer) are sequentially stacked.

The pixel defining layer PDL (or third insulating layer PDL) may include openings/holes Oa, Ob, and Oc that respectively (partially) expose the pixel electrodes E1a, E1b, and E1c. The pixel defining layer PDL may be positioned on the second insulating layer IL2. The pixel defining layer PDL may cover edges of the pixel electrodes E1a, E1b, and E1c. The pixel defining layer PDL may have an opening OP that (partially) exposes the etch stopper ES. The opening OP may have an undercut structure. A first portion/section of the opening OP may be farthest from the etch stopper ES and may have a reverse taper structure with a narrower bottom and a wider top. A second portion/section of the opening OP may be closest to the etch stopper ES. A third/intermediate/middle portion/section of the opening OP may be positioned between the first portion/section of the opening OP and the second portion/section of the opening OP in a depth direction of the opening OP (corresponding to the third direction z perpendicular to the substrate SB) and may be narrow than each of the first portion/section of the opening OP and the second portion/section of the opening OP in a direction parallel to the substrate SB. The width of the opening OP may gradually decrease and then gradually increase in the depth direction of the opening OP. The inner wall portion corresponding to third portion of the opening OP may protrude inward in the direction parallel to the substrate SB. The opening OP may be a trench extending in a lengthwise direction of the corresponding etch stopper ES. The opening OP may extend through the pixel defining layer PDL in the third direction z.

The light emitting member LM (or light emitting material layer LM) may be positioned on the pixel electrodes E1a, E1b, and E1c and the pixel defining layer PDL. The light emitting member LM may include layers stacked in the third direction z and may include portions separated from each other in the first direction x and/or the second direction y. Some layers of the light emitting member LM may continuously span the entire display area DA, and the other layers of the light emitting member may include disconnected portions respectively overlapping the pixel electrodes E1a, E1b, and E1c. A portion of the light emitting member LM (a light emitting material member) may be positioned on the etch stopper ES. The light emitting member LM may be separated by the undercut structure of the opening OP and may have discontinuity inside the opening OP. For example, the portion of the light emitting member LM overlapping the first pixel PXa and the portion of the light emitting member LM overlapping the second pixel PXb may be disconnected (and spaced from each other) inside the opening OP and may be respectively positioned over two opposite parts of the etch stopper ES. A portion of the light emitting member LM positioned on the pixel defining layer PDL may be spaced (by a gap of air) from a portion of the light emitting member LM positioned on the etch stopper ES. The discontinuity and/or separation may prevent unwanted light emission caused by current leakage/transmission between adjacent pixels through the light emitting member LM. When an image is displayed in a low gray, an unwanted increase in luminance due to a leakage current between adjacent pixels may be undesirably conspicuous. The discontinuity and/or separation of the light emitting member LM between the adjacent pixels may prevent the leakage current to prevent unwanted luminance increase. Advantageously, the quality of the displayed images may be satisfactory.

The common electrode E2 (or common electrode material layer E2) may be positioned on the light emitting member LM (or light emitting material layer LM). A portion of the common electrode E2 may be positioned on the etch stopper ES. The common electrode E2 may be separated over opposite parts of the etch stopper ES by the undercut structure of the opening OP. The common electrode E2 may include electrically disconnected portions that are spaced from each other inside the opening OP. One of the disconnected portions of the common electrode E2 may overlap the etch stopper ES inside the opening OP. The discontinuity and/or separation of the common electrode E2 may prevent a current leakage through the common electrode E2 between adjacent pixels.

In each of the pixels PXa, PXb, and PXc, the corresponding one of the pixel electrodes E1a, E1b, and E1c, the corresponding portion of the light emitting member LM, and the corresponding portion of the common electrode E2 may constitute the corresponding one of the light emitting diodes LEDa, LEDb, and LEDc. Each of the pixel electrode E1a, E1b, and E1c may be an anode; the corresponding portion of the common electrode E2 may a cathode.

FIG. 6 illustrates a schematic cross-sectional view of a light emitting member LM (or light emitting material layer LM) in a light emitting display device according to an embodiment.

Referring to FIG. 6, a stacked structure of the light emitting member LM associated with the pixels PXa, PXb, and PXc is illustrated. The light emitting member LM may be positioned between each of the pixel electrodes E1a, E1b, and E1c and the common electrode E2. The light emitting member LM may include a plurality of light emitting parts, for example, a first light emitting part LUa and a second light emitting part LUb. When the display device displays an image, the first light emitting part LUa and the second light emitting part LUb simultaneously emit light, thereby improving an image display characteristic of the display device.

The first light emitting part LUa may include a hole injection layer HIL, a hole transport layer HTL, emission layers LEa, LEb, and LEc, and an electron transport layer ETL.

Each of the hole injection layer HIL, the hole transport layer HTL, and the electron transport layer ETL may span the pixels PXa, PXb, and PXc and may overlap each of the pixel electrodes E1a, E1b, and E1c. The hole injection layer HIL, the hole transport layer HTL, and the electron transport layer ETL may be positioned not only inside the openings/holes Oa, Ob, and Oc of the pixel defining layer PDL, but also on the pixel definition layer PDL outside the openings Oa, Ob, and Oc. Disconnected portions of each of the hole injection layer HIL, the hole transport layer HTL, and the electron transport layer ETL (including a disconnected portion overlapping an etch stopper ES) may be separated over opposite parts of the etch stopper ES inside the corresponding opening OP. The hole injection layer HIL, the hole transport layer HTL, and/or the electron transport layer ETL may be optional.

The emission layers LEa, LEb, and LEc may respectively overlap the corresponding pixel electrodes E1a, E1b, and E1c. The emission layers LEa, LEb, and LEc may mainly be positioned within the corresponding openings/holes Oa, Ob, and Oc of the pixel defining layer PDL. The emission layers LEa, LEb, and LEc of adjacent pixels PXa, PXb, and PXc may be spaced from each other. The emission layers LEa, LEb, and LEc may not be positioned on the etch stopper ES. The emission layers LEa, LEb, and LEc may include organic materials that emit light of the primary colors displayed by respective pixels PXa, PXb, and PXc.

In each of the pixels PXa, PXb, and PXc, a corresponding one of auxiliary layers ALa, ALb, and ALc may be positioned between the corresponding one of the emission layers LEa, LEb, and LEc and the hole transport layer HTL. Each of the auxiliary layers ALa, ALb, and ALc may have a thickness that adjusts a length of a light path reciprocating between the corresponding one of the pixel electrodes E1a, E1b, and E1c and the common electrode E2 to match a resonance condition. At least one of the auxiliary layers ALa, ALb, and ALc block electrons of the corresponding emission layer from entering the hole transport layer HTL. For example, the auxiliary layer ALc of the third pixel PXc may block electrons of the emission layer LEc from entering the hole transport layer HTL. The first pixel PXa may display red, the second pixel PXb may display green, the third pixel PXc may display blue, the thickness of the auxiliary layer ALa may be the thickest, and the thickness of the auxiliary layer ALc may be the thinnest. The auxiliary layers ALa, ALb, and ALc may be optional.

The second light emitting part LUb may include a hole transport layer HTL, emission layers LEa, LEb, and LEc, a buffer layer BUF, and an electron transport layer ETL.

The emission layers LEa, LEb, and LEc of the second light emitting part LUb may have substantially the same functions and characteristics as the emission layers LEa, LEb, and LEc of the first light emitting part LUa.

In each of the pixels PXa, PXb, and PXc, a corresponding one of auxiliary layers ALa, ALb, and ALc may be positioned between the corresponding one of the emission layers LEa, LEb, and LEc and the hole transport layer HTL. The auxiliary layers ALa, ALb, and ALc of the second light emitting part LUb may have substantially the same functions and characteristics as the auxiliary layers ALa, ALb, and ALc of the first light emitting part LUa.

Each of the hole transport layer HTL, the buffer layer BUF, and the electron transport layer ETL may span the PXa, PXb, and PXc and may overlap each of the pixels E1a, E1b, and E1c. The hole transport layer HTL, the buffer layer (BUF), and the electron transport layer ETL may be positioned not only inside the openings Oa, Ob, and Oc of the pixel defining layer PDL, but also on the pixel definition layer PDL outside the openings Oa, Ob, and Oc. Disconnected portions of each of the hole transport layer HTL, the buffer layer BUF, and the electron transport layer ETL (including a disconnected portion overlapping the etch stopper ES) may be separated over opposite parts of the etch stopper ES inside the corresponding opening OP. The buffer layer BUF may include an insulating material. The buffer layer BUF and/or the electron transport layer ETL may be optional.

A charge generating layer CGL may be positioned between the first light emitting part LUa and the second light emitting part LUb. The charge generating layer CGL may include an n-type charge generating layer n-CGL and a p-type charge generating layer p-CGL. In each pixel PXa, PXb, or PXc, the n-type charge generating layer n-CGL and the p-type charge generating layer p-CGL may contact each other to form an NP junction. Electrons and holes may be simultaneously generated between the n-type charge generating layer n-CGL and the p-type charge generating layer p-CGL by the NP junction. The generated electrons may be transferred to the first light emitting part LUa through the n-type charge generating layer n-CGL, and the generated holes may be transferred to the second light emitting part LUb through the p-type charge generating layer p-CGL. Conductivity of the n-type charge generating layer n-CGL may be lower than that of the p-type charge generating layer p-CGL.

The n-type charge generating layer n-CGL may span the pixels PXa, PXb, and PXc and may overlap each of the pixel electrodes E1a, E1b, and E1c. The n-type charge generating layer n-CGL is positioned not only within the openings Oa, Ob, and Oc of the pixel defining layer PDL, but also on the pixel defining layer PDL outside the openings Oa, Ob, and Oc. Disconnected portions of the n-type charge generating layer n-CGL (including a disconnected portion overlapping the etch stopper ES) may be separated over opposite parts of the etch stopper ES.

The p-type charge generating layer p-CGL may span the pixels PXa, PXb, and PXc and may overlap each of the pixels E1a, E1b, and E1c. The p-type charge generating layer p-CGL is positioned not only within the openings Oa, Ob, and Oc of the pixel defining layer PDL, but also on the pixel defining layer PDL outside the openings Oa, Ob, and Oc. Disconnected portions of the p-type charge generating layer p-CGL (including a disconnected portion overlapping the etch stopper ES) may be separated over opposite parts of the etch stopper ES.

If the n-type charge generating layer n-CGL includes no discontinuities, when the display device 1 operates, a current of a pixel PXa, PXb, or PXc may significantly flow into one or more adjacent pixels PXa, PXb, and PXc through the continuous n-type charge generating layer n-CGL, thus an unintended pixel may emit light or luminance may unwantedly increase. If the p-type charge generating layer p-CGL includes no discontinuities, when the display device 1 operates, a current of a pixel PXa, PXb, or PXc may significantly flow into one or more adjacent pixels PXa, PXb, and PXc through the continuous p-type charge generating layer p-CGL, thus an unintended pixel may emit light or luminance may unwantedly increase. According to embodiments, disconnected portions of the n-type charge generating layer n-CGL and the p-type charge generation layer p-CGL may be separated by an undercut structure of the opening OP. The discontinuities and/or separation of the layers may reduce or prevent leakage of current through the n-type charge generating layer n-CGL and/or the p-type charge generating layer p-CGL, and to reduce or prevent unwanted light emission and/or unwanted luminance increase. Advantageously, satisfactory image quality may be attained.

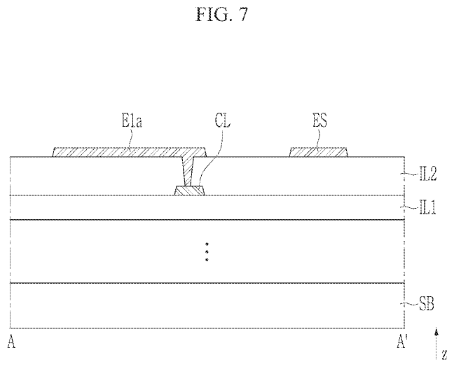

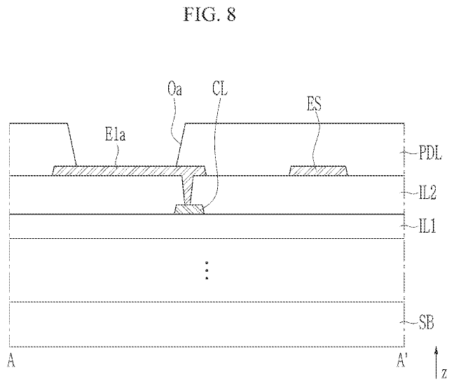

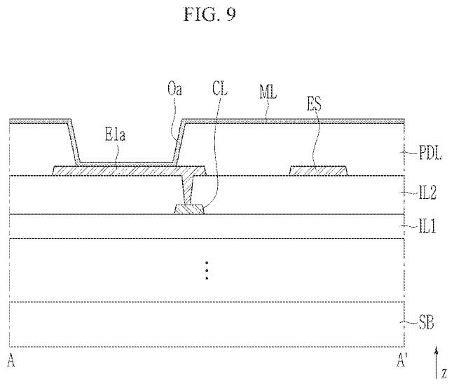

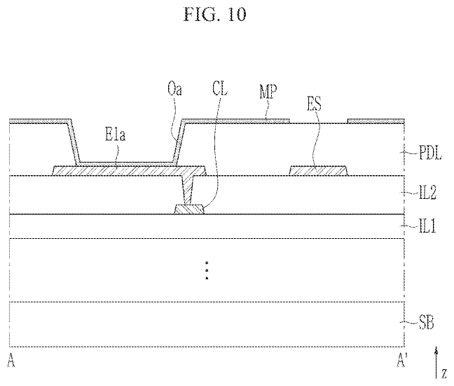

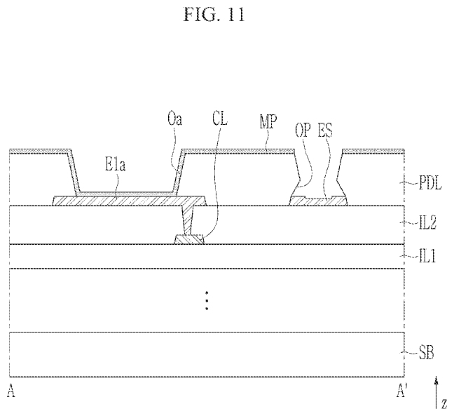

FIG. 7 to FIG. 13 illustrate cross-sectional views of structures associated with process steps of a manufacturing method of a light emitting display device according to one or more embodiments. The first pixel PXa among the pixels PXa, PXb, and PXc is shown as an example. The second and third pixels PXb and PXc may be formed through the same process steps as the first pixel PXa. One or more of the process steps may be described with reference to FIG. 4.

Referring to FIG. 7, the first insulating layer IL1 may be formed on the substrate SB. The first insulating layer IL1 may include an organic insulating material or an inorganic insulating material. After a conductive material layer is formed on the first insulating layer IL1, patterning may be performed on the conductive material layer to form the connector CL. The patterning may mean forming a predetermined pattern by removing portions of the layer through a photolithography process or the like. The connector CL may be multi-layered and may have a triple-layered structure of titanium (Ti)-aluminum (Al)-titanium (Ti) or molybdenum (Mo)-aluminum (Al)-titanium (Ti).

An insulating material layer may be formed on the first insulating layer IL1 and the connector CL and may be patterned to form the second insulating layer IL2 having a contact hole overlapping the connector CL. The second insulating layer IL2 may include an organic insulating material. The insulating material layer may be formed by coating a photosensitive polyimide (PSPI).

A conductive material layer may be formed on the second insulating layer IL2 and may be patterned may to form the pixel electrodes E1a, E1b, and E1c and the etch stopper ES. The patterning of the conductive material layer may include the following steps: applying (for example, coating) a photoresist on the conductive material layer; a photosensitive film pattern may be formed by selectively irradiating light and developing using a photomask; and the pixel electrodes E1a, E1b, and E1c and the etch stopper ES may be formed by wet-etching the conductive material layer by using the photosensitive film pattern as a mask. Accordingly, the etch stopper ES may be formed of the same material as the pixel electrodes E1a, E1b, and E1c in the same process (step). No additional masks or process steps for forming the etch stopper ES may be required. The pixel electrodes E1a, E1b, and E1c and the etch stopper ES may be multi-layered. For example, each of the pixel electrode E1a, E1b, and E1c and the etch stopper ES may include a triple-layer structure in which a transparent conductive oxide layer (for example, an indium tin oxide (ITO) layer), a metal layer (for example, a silver (Ag) layer), and a transparent conductive oxide layer (for example, an ITO layer) are sequentially stacked. The pixel electrodes E1a, E1b, and E1c may be respectively connected to the corresponding connectors CL through the corresponding contact holes formed in the second insulating layer IL2.

Referring to FIG. 4 and FIG. 8, an insulating material layer may be formed on the second insulating layer IL2, the pixel electrodes E1a, E1b, and E1c, and the etch stopper ES and then may be patterned to form the pixel defining layer PDL (or third insulating layer PDL) having the openings/holes Oa, Ob, and Oc overlapping with (and exposing) the pixel electrodes E1a, E1b, and E1c.

Referring to FIG. 9, a mask layer ML may be formed on the pixel defining layer PDL. The mask layer ML may be formed of a material that may be etched using an etchant having high selectivity with an uppermost layer of the pixel electrodes E1a, E1b, and E1c; the mask layer ML may include an oxide semiconductor. The oxide semiconductor may include an oxide of a metal such as zinc (Zn), indium (In), gallium (Ga), tin (Sn), or titanium (Ti), and/or may include a combination of a metal such as zinc (Zn), indium (In), gallium (Ga), tin (Sn), or titanium (Ti) and an oxide. The oxide semiconductor may include at least one of an indium-zinc oxide (IZO), an indium-gallium-zinc oxide (IGZO), an indium-zinc-tin oxide (IZTO), a zinc-tin oxide (ZTO), and a zinc oxide (ZnO). The mask layer ML may be an oxide semiconductor layer that may include an indium-gallium-zinc oxide (IGZO) and/or an indium-zinc oxide (IZO). The oxide semiconductor may have conductor or insulator characteristics depending on its oxygen content.

Referring to FIG. 10, a mask pattern MP may be formed by patterning the mask layer ML and may expose a portion of the pixel defining layer PDL that overlaps the etch stopper ES. The mask pattern MP may also expose portions of the substrate SB at predetermined positions for the grooves GR1, GR2, and GR3 described with reference to FIG. 3.

Referring to FIG. 4 and FIG. 11, the opening OP may be formed by dry etching the pixel defining layer PDL through an opening of the mask pattern MP. When the pixel defining layer PDL is etched in its thickness direction (in a direction perpendicular to the substrate SB) down to the etch stopper ES, the pixel defining layer PDL is no longer etched in the depth direction and may be further etched in other directions, including directions parallel to the substrate SB. Accordingly, the opening OP may have an undercut structure. The opening OP may a trench extending in a lengthwise direction of the etch stopper ES. When the opening OP is formed, a surface of the etch stopper ES may be partially etched, and a thickness of the etch stopper ES may be partially reduced. For example, the central portion of the etch stopper ES may be thinner than opposite parts/sides of the etch stopper ES.

When the opening OP is formed, the grooves GR1, GR2, and GR3 may be formed by etching the buffer layer BF and the substrate SB through openings of the mask pattern MP in the peripheral area LA. The opening OP and the grooves GR1, GR2, and GR3 may be formed by using the same mask pattern MP. The opening OP may be formed by providing an opening for forming the opening OP in the pattern of the mask used to form the grooves GR1, GR2, and GR3 without adding a mask.

Referring to FIG. 12, by removing the mask pattern MP, the pixel electrodes E1a, E1b, and E1c and the pixel defining layer PDL may be exposed. The mask pattern MP may be removed by wet etching. Since the mask layer ML may be formed of a material that may be etched using an etchant having a high selectivity with an uppermost layer of the pixel electrodes E1a, E1b, and E1c, when the mask pattern MP is removed by the wet etching, the pixel electrodes E1a, E1b, and E1c may not be damaged.

Referring to FIG. 4, FIG. 6, and FIG. 13, the light emitting member LM (or light emitting material layer LM) may be formed on the pixel electrodes E1a, E1b, and E1c and the pixel defining layer PDL. Since the etch stopper ES is exposed by the opening OP, a light emitting material member (i.e., a disconnected portion of the light emitting member LM) may also be formed on the etch stopper ES. In the light emitting member LM, the light emitting layers LEa, LEb, and LEc and the auxiliary layers ALa, ALb, and ALc may be selectively deposited in areas corresponding to respective pixels PXa, PXb, and PXc (i.e., corresponding to pixels E1a, E1b, and E1c) using a fine metal mask. Accordingly, the emission layers LEa, LEb, and LEc and auxiliary layers ALa, ALb, and ALc may not be substantially positioned on the pixel defining layer PDL and on the etch stopper ES. In the light emitting member LM, the charge generating layer CGL, the hole injection layer HIL, the hole transport layer HTL, the electron transport layer ETL, and the buffer layer BUF may be deposited in the entire display area DA through an open mask. Accordingly, the charge generating layer CGL, the hole injection layer HIL, the hole transport layer HTL, the electron transport layer ETL, and the buffer layer BUF may be positioned on the pixel defining layer PDL and on the etch stopper ES. Portions of the layers may be disconnected inside the opening OP and/or at opposite sides of the opening OP by the undercut structure of the opening OP. The discontinuities of the layers may reduce or prevent current leakage through the charge generating layer CGL between adjacent pixels PXa, PXb, and PXc, such that unwanted light emission and/or unwanted luminance increase may be prevented. The undercut structure of the opening OP for separating portions of the light emitting member LM, particularly the charge generating layer CGL, may be formed by simply performing dry etching without adding a mask.

Subsequently, referring to FIG. 5, a common electrode E2 (or common electrode material layer E2) may be positioned on the light emitting member LM (or light emitting material layer LM). The common electrode E2 may be deposited on the entire display area DA through an open mask. Accordingly, a portion of the common electrode E2 may be positioned on the etch stopper ES. The portion of the common electrode E2, i.e., a common electrode material member, may be disconnected from other portions of the common electrode E2 by the undercut structure of the opening OP.

FIG. 14 illustrates a cross-sectional view of a light emitting display device taken along line A-A′ indicated in FIG. 4 according to an embodiment.

Referring to FIG. 14, a position of the etch stopper ES may be different from the position of the etch stopper ES shown in FIG. 5. The etch stopper ES shown in FIG. 14 may be positioned on the first insulating layer IL1, and a lower surface of the etch stopper ES may directly contact an upper surface of the first insulating layer IL1. The opening OP overlapping with (and exposing) the etch stopper ES may be formed through the pixel defining layer PDL and into the second insulating layer IL2. The etch stopper ES may be formed of the same material as the connector CL in the same process. The etch stopper ES may be multi-layered, and may have a triple-layered structure of titanium (Ti)-aluminum (Al)-titanium (Ti) or molybdenum (Mo)-aluminum (Al)-titanium (Ti).

Even if the etch stopper ES is positioned on the first insulating layer IL1, the opening OP may have an undercut structure. Accordingly, portions of the light emitting member LM (or light emitting material layer LM) and portions of the common electrode E2 (or common electrode material layer E2) may be disconnected by the opening OP between the adjacent pixels PXa, PXb, and PXc, thereby reducing or preventing unwanted light emission and/or unwanted luminance increase. The manufacturing method may be substantially the same as or analogous to the above-described process except for forming the etch stopper ES in the step of forming the connector CL, forming the opening OP into the second insulating layer IL2, etc.

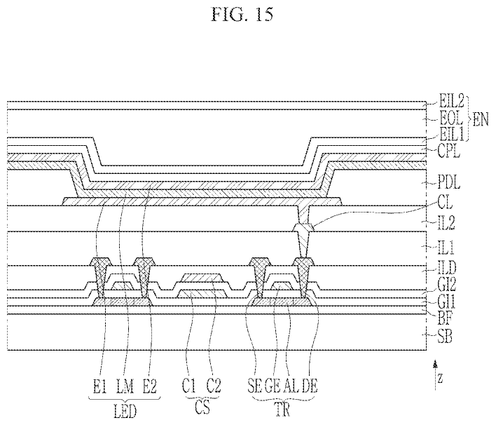

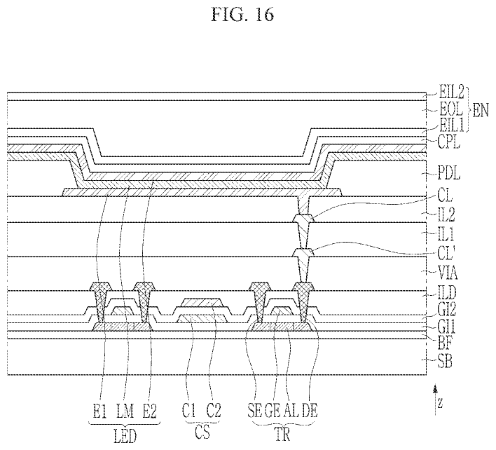

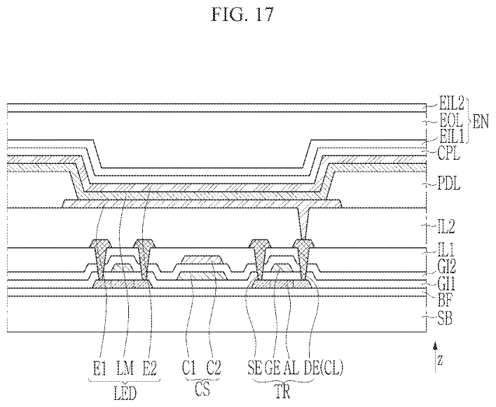

Each of FIG. 15, FIG. 16, and FIG. 17 illustrates a schematic cross-sectional view of one pixel area in a display panel according to an embodiment.

FIG. 15 illustrates a schematic cross-sectional view of a stacked structure of a display panel according to an embodiment. The cross-section shown in FIG. 15 may substantially correspond to one pixel area.

The display panel may include a substrate SB, a transistor TR formed on the substrate SB, and a light emitting diode LED connected to the transistor TR. The light emitting diode LED may correspond to a pixel PX. Structures positioned between the substrate SB and a first insulating layer IL1 in FIG. 15 may be substantially equivalent to structures not shown between the substrate SB and the first insulating layer IL1 in FIG. 5 and FIG. 14.

The substrate SB may be a flexible substrate including a polymer resin such as polyimide, polyamide, or polyethylene terephthalate. The substrate SB may be multi-layered. The substrate SB may include polymer resin layers and inorganic barrier layer that are alternately stacked. The substrate SB may be made of or include glass.

A buffer layer BF may be positioned on the substrate SB. The buffer layer BF may block impurities from the substrate SB when a semiconductor layer is formed, thereby improving characteristics of the semiconductor layer and flattening a surface of the substrate SB to reduce stress of the semiconductor layer. The buffer layer BF may include an inorganic insulating material such as a silicon nitride (SiNₓ), a silicon oxide (SiOₓ), or a silicon oxynitride (SiOₓN_{y}), and may be a single layer or a multilayer structure. The buffer layer BF may include amorphous silicon (a-Si).

A semiconductor layer AL of the transistor TR may be disposed on the buffer layer BF. The semiconductor layer AL may include a first region, a second region, and a channel region between the first region and the second region. The semiconductor layer AL may include one of amorphous silicon, polysilicon, and an oxide semiconductor. For example, the semiconductor layer AL may include a low temperature polycrystalline silicon (LTPS), or an oxide semiconductor material including at least one of zinc (Zn), indium (In), gallium (Ga), and tin (Sn). For example, the semiconductor layer AL may include an indium-gallium-zinc oxide (IGZO).

A first gate insulating layer GI1 may be disposed on the semiconductor layer AL. The first gate insulating layer GI1 may include an inorganic insulating material such as a silicon nitride, a silicon oxide, or a silicon oxynitride, and may be a single layer or a multilayer structure.

A first gate conductive layer may include a gate electrode GE of the transistor TR and a first electrode C1 of a capacitor CS and may be positioned on the first gate insulating layer GI1. The first gate conductive layer may include molybdenum (Mo), aluminum (Al), copper (Cu), and/or titanium (Ti), and may be a single layer or a multilayer structure.

A second gate insulating layer GI2 may be positioned on the first gate conductive layer. The second gate insulating layer GI2 may include an inorganic insulating material such as a silicon nitride, a silicon oxide, or a silicon oxynitride, and may be a single layer or a multilayer structure.

A second gate conductive layer may include a second electrode C2 of the capacitor CS and may be positioned on the second gate insulating layer GI2. The second gate conductive layer may include molybdenum (Mo), aluminum (Al), copper (Cu), and/or titanium (Ti), and may be a single layer or a multilayer structure.

An interlayer insulating layer ILD may be positioned on the second gate insulating layer GI2 and the second gate conductive layer. The interlayer insulating layer ILD may include an inorganic insulating material such as a silicon nitride, a silicon oxide, or a silicon oxynitride, and may be a single layer or a multilayer structure.

A first data conductive layer may include a first electrode SE and a second electrode DE of the transistor TR and may be positioned on the interlayer insulating layer ILD. The first electrode SE and the second electrode DE may be respectively connected to the first region and the second region of the semiconductor layer AL through contact holes formed in the insulating layers GI1, GI2, and ILD. One of the first electrode SE and the second electrode DE may be a source electrode, and the other may be a drain electrode. The first data conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or a multilayer structure. The first data conductive layer may include a lower layer including a refractory metal (such as molybdenum, chromium, tantalum, and titanium), an intermediate layer including a metal having low resistivity (such as aluminum, copper, and silver), and an upper layer including a refractory metal. The first data conductive layer may have a triple-layered structure of titanium (Ti)-aluminum (Al)-titanium (Ti).

The first insulating layer IL1 may be positioned on the first data conductive layer. The first insulating layer IL1 may be an organic insulating layer. The first insulating layer IL1 may include an organic insulating material such as a general purpose polymer (such as poly(methyl methacrylate) or polystyrene), a polymer derivative having a phenol-based group, an acryl-based polymer, an imide-based polymer, a polyimide, or a siloxane-based polymer.

A second data conductive layer may include the connector CL and may be positioned on the first insulating layer IL1. The connector CL may be connected to the second electrode DE of the transistor TR through a contact hole formed in the first insulating layer IL1. The second data conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or a multilayer structure. For example, the second data conductive layer may have a triple-layered structure of titanium (Ti)-aluminum (Al)-titanium (Ti).

A second insulating layer IL2 may be positioned on the second data conductive layer. The second insulating layer IL2 may be an organic insulating layer. The second insulating layer IL2 may include an organic insulating material such as a general purpose polymer (such as poly(methyl methacrylate) or polystyrene), a polymer derivative having a phenol-based group, an acryl-based polymer, an imide-based polymer, or a siloxane-based polymer.

A pixel electrode E1 of the light emitting diode LED may be positioned on the second insulating layer IL2. The pixel electrode E1 may be connected to the connector CL through a contact hole formed in the second insulating layer IL2. Accordingly, the pixel electrode E1 may be electrically connected to the second electrode DE of the transistor IR to receive a driving current for controlling brightness of the light emitting diode LED. The transistor TR to which the pixel electrode E1 is connected may be a driving transistor, or may be a transistor electrically connected to the driving transistor. The pixel electrode E1 may be made of a reflective conductive material, a translucent conductive material, and/or a transparent conductive material. The pixel electrode E1 may include a transparent conductive material such as an indium tin oxide (ITO) or an indium zinc oxide (IZO). The pixel electrode E1 may include a metal such as lithium (Li), calcium (Ca), aluminum (Al), silver (Ag), magnesium (Mg), or gold (Au), or a metal alloy of some of the metal materials. The pixel electrode E1 may be multi-layered and may have a triple-layered structure of ITO-silver (Ag)-ITO.

A pixel defining layer PDL may be an organic insulating layer and may be positioned on the second insulating layer IL2. The pixel defining layer PDL may have an opening/hole overlapping with (and exposing) the pixel electrode E1.

A light emitting member LM of the light emitting diode LED may be positioned on the exposed portion of the pixel electrode E1, and a common electrode E2 of the light emitting diode LED may be positioned on the light emitting member LM. The common electrode E2 may include a thin metal layer having desirable light transmittance and/or may include a metal alloy having a low work function such as calcium (Ca), barium (Ba), magnesium (Mg), aluminum (Al), or silver (Ag). The common electrode E2 may include a transparent conductive oxide such as an iridium tin oxide (ITO) or an indium zinc oxide (IZO). A common voltage may be applied to the common electrode E2.

The pixel electrode E1, the light emitting member LM, and the common electrode E2 of each pixel PX form the light emitting diode LED, which may be an organic light emitting diode or an inorganic light emitting diode. The pixel electrode E1 may be an anode of the light emitting diode LED, and the common electrode E2 may be a cathode of the light emitting diode LED.

A capping layer CPL may be positioned on the common electrode E2. The capping layer CPL may improve light efficiency through refractive index adjustment. The capping layer CPL may entirely cover a surface of the common electrode E2. The capping layer CPL may include an organic insulating material or an inorganic insulating material.

An encapsulation layer EN may be positioned on the capping layer CPL. The encapsulation layer EN may encapsulate the light emitting diode LED to prevent external moisture or oxygen from substantially penetrating into the display panel. The encapsulation layer EN may be a thin film encapsulation layer including one or more inorganic layers EIL1 and EIL2, and one or more organic layers EOL.

A touch sensor layer (not shown) including touch electrodes may be positioned on the encapsulation layer EN. The touch electrodes may have a mesh structure having an opening overlapping the light emitting diode LED. An anti-reflective layer (not shown) for reducing reflection of external light may be positioned on the touch sensor layer.

In the display panel illustrated in FIG. 16, in comparison with the display panel shown in FIG. 15, a planarization layer VIA is positioned between the interlayer insulating layer ILD and the first insulating layer IL1l, and a data conductive layer including a connector CL′ may be disposed between the planarization layer VIA and the first insulating layer IL1. The connector CL′ may be connected to the second electrode DE of the transistor TR through a contact hole formed in the planarization layer VIA, and the connector CL may be connected to the connector CL′ through a contact hole formed in the first insulating layer IL1. The data conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or a multilayer structure. For example, the data conductive layer may have a triple-layered structure of titanium (Ti)-aluminum (Al)-titanium (Ti). The planarization layer VIA may be an organic insulating layer. The planarization layer VIA may include an organic insulating material such as a general purpose polymer (such as poly(methyl methacrylate) or polystyrene), a polymer derivative having a phenol-based group, an acryl-based polymer, an imide-based polymer, or a siloxane-based polymer.

Structures positioned between the substrate SB and a first insulating layer IL1 in FIG. 16 may be substantially equivalent to structures not shown between the substrate SB and the first insulating layer IL1 in FIG. 5 and FIG. 14.

In the display panel shown in FIG. 17, compared with the display panel shown in FIG. 15, the first insulating layer IL1 is positioned directly on the second gate insulating layer GI2. The first insulating layer IL1 may include an inorganic insulating material such as a silicon nitride, a silicon oxide, or a silicon oxynitride, and may be a single layer or a multilayer structure. The pixel electrode E1 may be connected to the second electrode DE of the transistor TR through a contact hole formed in the second insulating layer IL2.

Structures positioned between the substrate SB and a first insulating layer IL1 in FIG. 17 may be substantially equivalent to structures not shown between the substrate SB and the first insulating layer IL1 in FIG. 5 and FIG. 14. The connector CL shown in FIG. 5 and FIG. 14 may be substantially equivalent to the second electrode DE shown in FIG. 17.

While examples of embodiments have been described, practical embodiments are not limited to the described embodiments. Practical embodiments are intended to cover various modifications and equivalent arrangements within the scope of the appended claims.

What is claimed is:

1. A light emitting display device, comprising:
a substrate;
a transistor overlapping the substrate;
a first insulating layer overlapping the transistor;
a second insulating layer overlapping the first insulating layer;
a pixel electrode directly contacting the second insulating layer and electrically connected to the transistor;
a conductive member directly contacting at least one of the first insulating layer and the second insulating layer;
a third insulating layer overlapping the second insulating layer, comprising a hole, and comprising an opening, wherein the hole exposes the pixel electrode, and wherein the opening exposes the conductive member; and
a light emitting material layer overlapping the pixel electrode inside the hole, overlapping the third insulating layer, and having a discontinuity inside the opening.

2. The light emitting display device of claim 1, wherein the opening has an undercut structure.

3. The light emitting display device of claim 1, wherein a first section of the opening is positioned between a second section of the opening and a third section of the opening in a depth direction of the opening and is narrower than each of the second section of the opening and the third section of the opening.

4. The light emitting display device of claim 1, wherein the light emitting material layer comprises a charge generating layer, and wherein the charge generating layer is partially positioned inside the opening and exposes the conductive member inside the opening.

5. The light emitting display device of claim 4, wherein the charge generating layer includes a disconnected portion disposed inside the opening and overlapping the conductive member.

6. The light emitting display device of claim 1, further comprising: a common electrode material layer overlapping each of the light material layer and the third insulating layer, wherein the common electrode material layer has a gap inside the opening.

7. The light emitting display device of claim 6, wherein the common electrode material layer includes a disconnected portion disposed inside the opening and overlapping the conductive member.

8. The light emitting display device of claim 1, wherein the conductive member includes a transparent conductive oxide layer.

9. The light emitting display device of claim 1, wherein the conductive member includes a first transparent conductive oxide layer, a metal layer, and a second transparent conductive oxide layer that are sequentially stacked, and wherein at least one of the first transparent conductive oxide layer and the second transparent conductive oxide layer directly contacts the second insulating layer.

10. The light emitting display device of claim 1, wherein the conductive member is made of a same material as the pixel electrode in a same process.

11. The light emitting display device of claim 1, further comprising: a connector disposed between the first insulating layer and the second insulating layer, electrically connected to the pixel electrode, and electrically connected to at least one of a semiconductor layer of the transistor, a drain electrode of the transistor, and a source electrode of the transistor, wherein the conductive member is made of a same material as the connector in a same process.

12. The light emitting display device of claim 11, wherein the opening extends through the third insulating layer and the second insulating layer.

13. The light emitting display device of claim 1, wherein the light emitting material layer includes a hole transport layer, an electron transport layer, and a light emitting layer disposed between the hole transport layer and the electron transport layer and overlapping the pixel electrode.

14. A light emitting display device, comprising:
a substrate;
a transistor overlapping the substrate;
a first insulating layer overlapping the transistor;
a second insulating layer overlapping the first insulating layer;
a pixel electrode directly contacting the second insulating layer and electrically connected to the transistor;
a conductive member directly contacting at least one of the first insulating layer and the second insulating layer;
a third insulating layer overlapping the second insulating layer, comprising a hole, and comprising an opening, wherein the hole exposes the pixel electrode, and wherein the opening exposes the conductive member; and
a light emitting material layer overlapping the pixel electrode inside the hole, overlapping the third insulating layer, and comprising two disconnected portions that are disposed inside the opening and are spaced from each other by a gap.

15. The light emitting display device of claim 14, wherein the conductive member is electrically disconnected from all transistors of the light emitting display device.

16. The light emitting display device of claim 14, wherein the conductive member directly contacts the second insulating layer and includes a transparent conductive oxide layer.

17. The light emitting display device of claim 14, wherein the conductive member is made of a same material as the pixel electrode in a same process.

18. The light emitting display device of claim 14, wherein the conductive member directly contacts the first insulating layer and includes a refractory metal layer.

19. The light emitting display device of claim 14, further comprising: a common electrode material layer overlapping the light emitting material layer inside the hole, wherein the common electrode material layer has a discontinuity inside the opening.

20. The light emitting display device of claim 14, wherein the opening has an undercut structure.
